(19) United States
(12) Patent Application Publication
(10) Pub. No.: US 2008/0155372 A1
(43) Pub. Date: Jun. 26, 2008

(54) Methods and apparatus for improving error indication performance in systems with low-density parity check codes

(75) Inventors: David Kravitz, Cambridge, MA (US); Samuel J. MacMullan, Carlisle, MA (US); Andrew Thangaraj, Chennai (IN); Jianhan Liu, Acton, MA (US)

Correspondence Address: FIALA & WEAVER, P.L.L.C.;C/O INTELLEVATE, P.O. BOX 52050, MINNEAPOLIS, MN, 55402, US

(73) Assignee: Radiospire Networks, Inc., Concord, MA (US)

(21) Appl. No.: 11/642,885

(22) Filed: Dec. 21, 2006

(51) Int. Cl. H03M 13/05; G06F 11/10

(52) U.S. Cl. 714/752; 714/E11.032

(57) ABSTRACT

The present invention is directed to methods and apparatus for improving error indication performance in systems employing low-density parity check (LDPC) codes. In one aspect, a method and apparatus for providing error indication based on full LDPC parity check re-encoding are provided. In an embodiment, an LDPC encoder is employed at the receiver to re-encode the parity bits. In another embodiment, the parity bits are re-encoded recursively based on information readily available at the decoder of the receiver. In another aspect, a method and apparatus for providing error indication based on partial LDPC parity check re-encoding are provided. In an embodiment, partial checksum information is determined based on the decoder output and used to provide error indication. In a further aspect, a hybrid CRC checking and LDPC parity check re-encoding approach is provided. This approach further enhances error indication performance by reducing the miss probability compared to pure LDPC parity check re-encoding.

### BACKGROUND OF THE INVENTION

1. Field of the Invention

The present invention is related to improving error indication performance in systems employing low-density parity check codes.

2. Background

Low-density parity check codes (LDPC) are becoming increasingly popular in communications systems due to their capacity-approaching performance and parallel-decoding structure that allows reduced complexity implementation. LDPC codes with a dual-diagonal structured parity check matrix offer the additional advantage of encoding with linear complexity.

An important requirement in many communications systems is a reliable indication whether demodulated and decoded information is correct or in error. For instance, data communications systems often use this indication to determine whether, a particular packet requires retransmission. Further, knowledge of the position of errors can be exploited to perform error concealment on received information. For example, audio and video systems can use information bits marked as good to estimate those that are labeled as being in error.

Typically, the effectiveness of an error indication approach can be characterized by the false alarm and miss probabilities (P_{FA} and P_{M}, respectively) for a frame of information bits in a codeword. A false alarm occurs when the error indicator is true when in reality the frame was correct. A miss occurs when the error indicator is false when in reality the frame was in error. A related measure, the detection probability, P_{D}, is simply equal to 1-P_{M}. False alarms and misses are both undesirable events, but in general miss events are more damaging. For example, in data communications, false alarms could trigger unnecessary retransmissions, reducing throughput. In contrast, a miss would result in the passage of erroneous data to higher layers, potentially causing major disruptions such as link loss. Some applications require P_{M} to be lower than 10⁻⁷.

It is desirable to provide effective error indication for LDPC codes. LDPC codes can often be represented in systematic form with each codeword separated into information bits and parity check bits as shown in FIG. 1.

Current methods to provide error indication for a systematic LDPC codeword include the use of LDPC parity checks, a cyclic redundancy code (CRC) inserted in the information bits, and/or an outer code such as a Reed Solomon (RS) or Bose, Ray-Chaudhuri, Hocquenghem (BCH) code that provides error correction and detection capability. However, error indication based on LDPC parity checks results in large P_{FA}. Error indication based on short CRCs results in unacceptable P_{M} whereas, long CRCs, which can provide acceptable error indication performance, introduce overhead that significantly reduces the supported data rate. Also, RS and BCH codes introduce substantial extra complexity for encoding and decoding.

What is needed therefore, given the current lack of practical and effective error indication solutions for LDPC codes, is an improved error indication approach for LDPC codes which exhibits low P_{FA} and P_{M} and introduces little overhead while adding minimal additional complexity.

### BRIEF SUMMARY OF THE INVENTION

The present invention is directed to methods and apparatus for improving error indication performance in systems employing low-density parity check codes.

In one aspect, a method and apparatus for providing error indication based on full LDPC parity check re-encoding are provided. In an embodiment, an encoder is employed at the receiver to re-encode the LDPC parity bits. In another embodiment, the parity bits are re-encoded recursively based on information readily available at the decoder of the receiver.

In another aspect, a method and apparatus for providing error indication based on partial LDPC parity check re-encoding are provided. In an embodiment, partial checksum information is determined based on the decoder output and used to provide error indication.

In a further aspect, a hybrid CRC checking and LDPC parity check re-encoding approach is provided. This approach further enhances error indication performance by reducing the miss probability compared to pure LDPC parity check re-encoding.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present invention and, together with the description, further serve to explain the principles of the invention and to enable a person skilled in the relevant art(s) to make and use the invention.

FIG. 1 illustrates a systematic LDPC codeword.

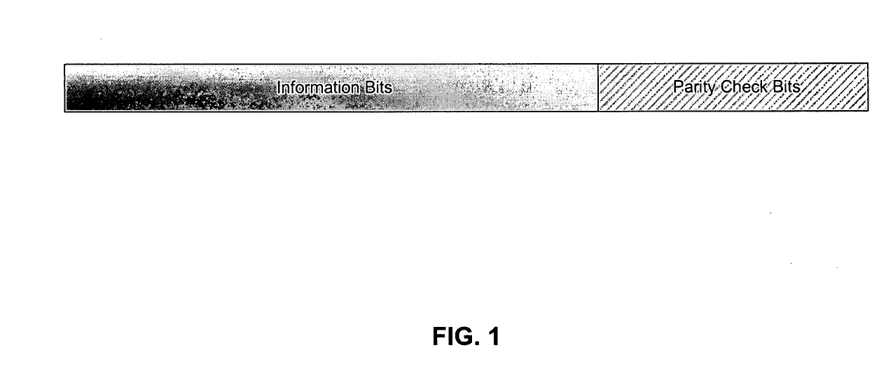

FIG. 2 is a process flowchart that illustrates error indication using LDPC parity checking.

FIG. 3 illustrates an LDPC codeword with a CRC.

FIG. 4 is a process flowchart that illustrates error indication using LDPC parity checking and CRC checking.

FIG. 5 is a block diagram that illustrates a method for error indication based on LDPC parity check re-encoding.

FIG. 6 illustrates an implementation of a method for error indication based on LDPC parity check re-encoding.

FIG. 7 is a process flowchart that illustrates a hybrid method for error indication using LDPC parity check re-encoding and CRC checking.

FIG. 8 is a high-level illustration of an apparatus for implementing error indication based on LDPC parity check re-encoding.

FIG. 9 is a high-level illustration of another apparatus for implementing error indication based on LDPC parity check re-encoding.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

### DETAILED DESCRIPTION OF THE INVENTION

In the following, conventional error indication approaches for LDPC codes are described followed by alternative approaches according to embodiments of the present invention. In section I, error indication approaches using LDPC parity checking and using CRC checking and LDPC parity checking are described. In section II, alternative error indication for LDPC codes with dual-diagonal parity check matrix is presented. As will be described, this approach significantly improves P_{FA} and P_{M}, and several methods based thereon will be provided.

### I. Conventional Error Indication for LDPC Codes

A. Error Indication Using LDPC Parity Checking

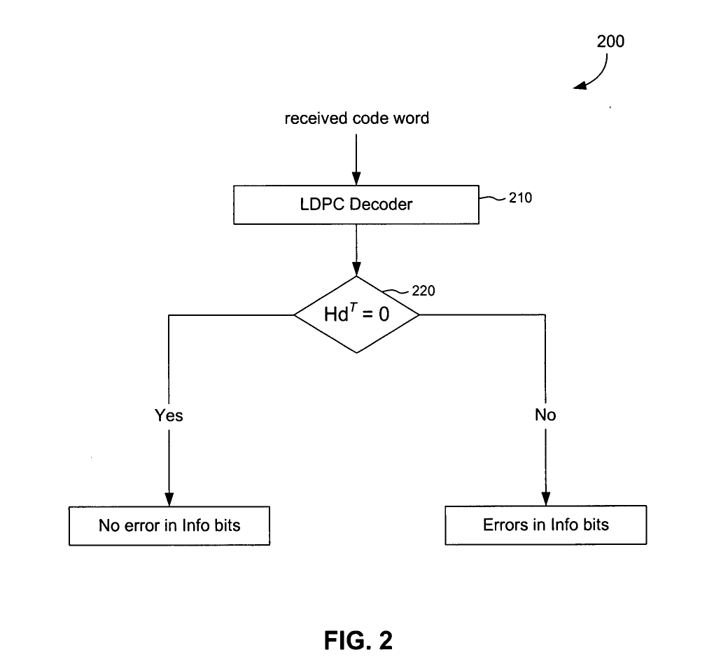

FIG. 2 is a process flowchart 200 that illustrates error indication using LDPC parity checking. In process 200, d is the LDPC decoder output vector of length M that results from the decoding, in step 210, of a codeword transmitted according to a (N×M) parity check matrix H of an LDPC code.

Theoretically, any codeword c satisfying the parity check constraints of matrix H satisfies the product Hc^{T}=0, where c^{T} denotes the transpose of vector c.

Accordingly, error indication using LDPC parity checking, as illustrated in process 200, works by evaluating in step 220 the matrix product Hd^{T} to determine if errors occurred in the decoder output d. If decoder output d satisfies Hd^{T}=0, the transmitted codeword is assumed to have been correctly decoded. Otherwise, information bit errors are presumed to exist in the decoder output vector d.

Note that error indication using LDPC parity checking only checks if the decoder output vector represents a valid codeword to decide whether or not errors exist in the decoder output. As a result, in the case that, due to transmission and/or decoding errors, a transmitted codeword a is decoded as another valid codeword b (i.e., Hb^{T}=0), error indication based on this method results in a miss. In other words, the decoder output is in error but is ruled to be correct.

In addition, oftentimes in cases where Hd^{T}≠0, the erroneous bits happen to be only in parity check bits of the transmitted codeword. This method will thus determine that information bit errors exist in the decoder output, thereby generating a false alarm.

Consider, for example, the dual-diagonal structured matrix H associated with a rate ⅔ LDPC code illustrated in equation (1) below, where I denotes a (P×P) identity matrix and X and X_{i,j} are (P×P) shifted identity matrices or zero matrices.

$$H = [ \begin{matrix}{X}_{1 , 1} & {X}_{1 , 2} & ⋯ & {X}_{1 , 16} & X & I & 0 & ⋯ & ⋯ & 0 \\ {X}_{2 , 1} & {X}_{2 , 2} & ⋯ & {X}_{2 , 16} & 0 & I & I & 0 & ⋯ & 0 \\ {X}_{3 , 1} & {X}_{3 , 2} & ⋯ & {X}_{3 , 16} & 0 & 0 & I & I & ⋯ & 0 \\ ⋮ & ⋮ & ⋮ & ⋮ & ⋮ & ⋮ & ⋮ & ⋮ & ⋮ & ⋮ \\ ⋮ & ⋮ & ⋮ & ⋮ & I & ⋮ & ⋮ & ⋮ & ⋮ & ⋮ \\ ⋮ & ⋮ & ⋮ & ⋮ & ⋮ & ⋮ & ⋮ & ⋮ & ⋮ & ⋮ \\ {X}_{7 , 1} & {X}_{7 , 2} & ⋯ & {X}_{7 , 16} & 0 & 0 & ⋯ & 0 & I & I \\ {X}_{8 , 1} & {X}_{8 , 2} & ⋯ & {X}_{8 , 16} & X & 0 & ⋯ & ⋯ & 0 & I\end{matrix} ] \qquad ( 1 )$$

In matrix H, the first 16P columns correspond to the codeword information bits and the last 8P columns correspond to parity check bits, yielding a code of length 24P.

As such, a codeword c satisfying H is split into a message vector m and 8 parity vectors p₁, p₂, p₃, p₄, p₅, p₆, p₇, and p₈. In vector notation, c=[m p₁ p₂ p₃ p₄ p₅ p₆ p₇ p8]. Also, as noted above, Hc^{T}=0.

Note that the LDPC code characterized by H as given by equation (1) is “irregular” in that the column degree Dᵢ (the number of ones in a column i) varies from column-to-column. In particular, the last 7P columns have lower degree than the first 17P columns. Typically, the likelihood that the i^{th} bit in an LDPC codeword is in error is directly related to Dᵢ. Accordingly, the parity check bit error rate is higher than the information bit error rate. As a result, in many cases when Hd^{T}≠0, there are no errors in the information bits; rather, errors are confined to parity checks.

Performance of error indication using LDPC parity checking is summarized in Table 1 below, which illustrates simulation results based on an LDPC codeword of length 1728. The results of Table 1 are calculated over at least 50 million codeword errors, and P_{M} is assigned a rough range if no miss occurs in simulation over at least 50 million codewords. The frame error rate (FER) is determined offline by directly comparing transmitted and received information bits. A frame is in error if information bits are in error in the received frame.

Table 1 shows a high P_{FA} for a wide range of FER for this approach. For example, for FER approximately 1% (1.3%), over half the codewords for which Hd^{T}≠0 result in false alarms (0.66%).

TABLE 1

| FER | P_{FA} | P_{M} |
|---|---|---|
| 0.29 | 0.078 | <2.0 × 10⁻⁸ |
| 0.077 | 0.031 | 3.1 × 10⁻⁸ |
| 0.013 | 0.0066 | <2.0 × 10⁻⁸ |

B. Error Indication Using CRC Checking and LDPC Parity Checking

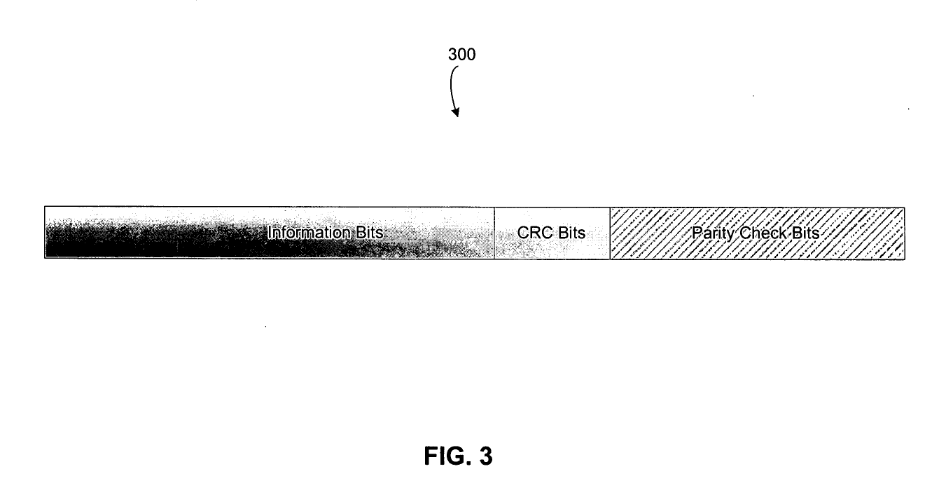

Another approach to provide error indication inserts a cyclic redundancy code (CRC) into the information bits and uses CRC checking to reduce the probability of false alarm. An LDPC codeword 300 having CRC bits inserted therein is illustrated in FIG. 3.

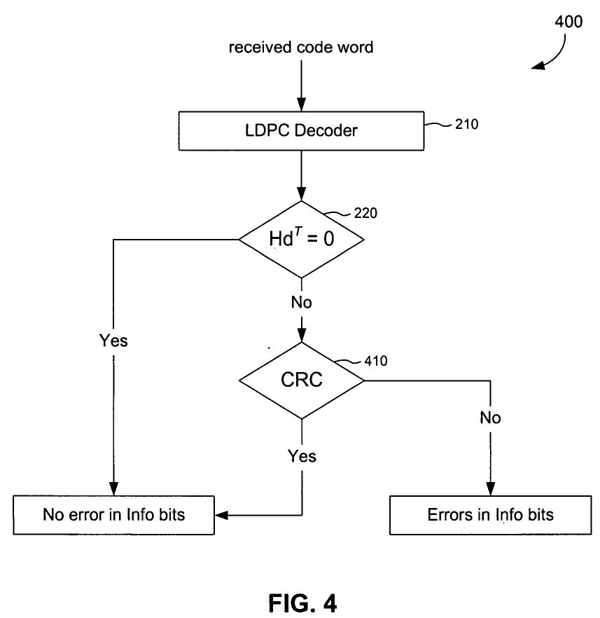

FIG. 4 is a process flowchart 400 that illustrates an error indication method using CRC checking and LDPC parity checking. Process 400 begins by performing an LDPC parity check test, in step 220, on the received decoder output d. This is typically done by evaluating if Hd^{T}=0, where H is the parity check matrix of the transmitted codeword. If Hd^{T}=0, then the decoder output d is a valid codeword and no errors are considered to have occurred in the information bits. On the other hand, if Hd^{T}≠0, the method assumes that errors could have occurred in either the information bits, the parity check bits, or both. The method then proceeds to perform a CRC check, in step 410, on the information bits. If the CRC check is successful, the method assumes that no errors occurred in the information bits. Otherwise, the method decides that errors have occurred at least in the information bits.

Note that augmenting the LDPC parity check test with a CRC check as done in process 400 eliminates false alarms due to errors that are restricted to parity check bits. However, the method illustrated in process 400 can still result in misses due to the LDPC decoder erroneously decoding (due to transmission and/or decoding errors) a transmitted codeword as another valid codeword, or if errors in the CRC bits line up with errors in the information bits in such a way as to result in a successful CRC check despite errors in the information bits. Accordingly, the miss probability achievable using a combined CRC checking and LDPC parity checking approach is not superior to that achieved by solely using LDPC parity checking. In addition, in the strict sense, false alarms can still occur when errors occur only in the CRC check bits and parity bits but not the information bits. However, the probability of this is very small and the results presented herein do not include these events as false alarms. Rather, these events are counted as detections.

Tables 2 and 3 below illustrate the performance of the combined CRC checking and LDPC parity checking approach for CRC codes of length 16 and 24, respectively.

Note, as defined herein, P_{FA} is always equal to zero as the combined approach eliminates false alarms. The miss probability performance is directly related to the CRC code length. Note for example, from tables 2 and 3 below, that for a frame error rate of approximately 7.6%, the miss probability using a CRC code of length 24 is approximately one order of magnitude lower than that obtained using a CRC code of length 16. Additional simulations (not illustrated herein) show that a CRC code of length 32 reduces to negligible the miss probability due to the CRC bit errors lining up with errors in the information bits. Nonetheless, the miss probability of the combined CRC checking and parity checking approach remains high due to the fact that misses still occur when the LDPC decoder erroneously yields valid codewords.

Note that in the simulations leading to the results in Tables 2 and 3, the length 16 CRC is used with a codeword of length 2016 whereas the length 24 CRC is used with a codeword of length 1728. For each codeword, H is defined as provided in equation (1) with P=84 and P=72, respectively.

TABLE 2

| FER | P_{FA} | P_{M} |
|---|---|---|
| 0.677 | 0 | 6.1 × 10⁻⁶ |
| 0.307 | 0 | 1.8 × 10⁻⁶ |
| 0.076 | 0 | 2.1 × 10⁻⁷ |

TABLE 3

| FER | P_{FA} | P_{M} |
|---|---|---|
| 0.90 | 0 | 1.3 × 10⁻⁷ |
| 0.29 | 0 | 9.3 × 10⁻⁸ |
| 0.077 | 0 | <2.0 × 10⁻⁸ |

### II. Error Indication Using LDPC Parity Check Re-Encoding

As discussed above, error detection based solely on using LDPC parity checking (i.e., evaluating Hd^{T}=0) results in a high P_{FA} as errors are often confined to the parity bits. On the other hand, augmenting LDPC parity checking with CRC checking reduces P_{FA} but introduces a higher P_{M} and increased overhead.

In the following, alternative approaches for error indication will be provided, wherein given that H is dual-diagonal structured, an encoder or functionally equivalent modules can be used at the receiver to significantly reduce P_{FA} while only introducing a small increase in P_{M}. Specifically, the encoder (or functionally equivalent modules) generates all or a subset of the LDPC parity check bits by re-encoding hard decisions on the LDPC decoded information bits. Error indication is then based on the comparison between the re-encoded parity check bits and the decoded parity check bits. In implementation, this comparison may be performed in a variety of ways as will be further described below.

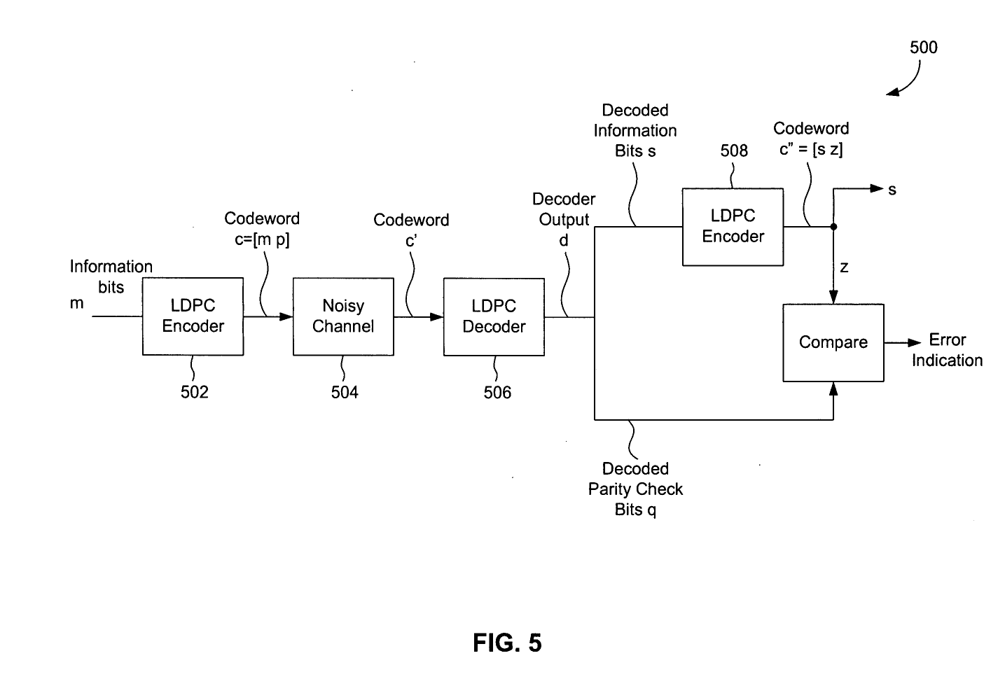

FIG. 5 is a block diagram 500 that conceptually illustrates this approach for error indication based on re-encoding LDPC parity check bits. Information bit vector m is encoded by an LDPC encoder 502 at the transmitter to generate an LDPC codeword c. Codeword c, as described above, contains information bits and parity check bits, denoted as m and p in FIG. 5. Note that, in this notation, p represents a concatenation of one or more component parity vectors.

Codeword c is transmitted over a noisy channel 504 and received as codeword c′ at the receiver. Codeword c′ may or may not be a valid codeword with respect to the LDPC code used by encoder 502 at the transmitter.

Codeword c′ is decoded at the receiver using an LDPC decoder 506 to generate the decoder output vector d. Decoder output vector d contains an information part and a parity part, shown in FIG. 5 as decoded information bit vector s and decoded parity check bit vector q. Note that in case no errors occur during transmission and/or decoding, s and q should be respectively identical to m and p. In such a case, re-encoding s using the same LDPC encoder as used at the transmitter should generate parity check bits identical to p, which also should be identical to q.

Accordingly, in FIG. 5, the decoded information bit vector s is re-encoded using an LDPC encoder 508 to generate a re-encoded codeword c″ having an information bit vector s and a parity bit vector z. Error indication is then performed by comparing the re-encoded parity bit vector z and the decoded parity check bit vector q.

Based on the result of the parity bit comparison, various rules can be used to decide whether or not errors have occurred in the information bits for the purpose of providing error indication. Note that parity bit vectors z and q will only be equal if both s and q are correctly decoded (i.e., s identical to m, and q identical to p), or in the unique case when both s and q are incorrectly decoded (due to transmission and/or decoding errors) and errors in s and q line up with each others such that the encoding of s results in q as a parity bit vector. For any other cases (i.e., either s or q is incorrectly decoded, or both are incorrectly decoded excepting that unique case), z and q will not be equal.

In the following, methods and apparatus for implementing the error indication approach based on LDPC parity check re-encoding are provided. In particular, these methods and apparatus provide different ways for implementing the parity bit comparison described above and therefore may vary both in performance and in cost of implementation.

At a high level, these methods include receiving an LDPC-encoded codeword; decoding the LDPC-encoded codeword to generate decoded information bits and parity check bits; generating at least a portion of a checksum bit vector based on at least the decoded information bits and parity check bits; and generating an error indicator for the received LDPC-encoded codeword based on the generated portion of the checksum bit vector. In an embodiment, the generation of the checksum bit vector includes LDPC re-encoding the decoded information bits to generate re-encoded parity check bits and summing the generated re-encoded parity check bits and respective ones of the decoded parity check bits to generate the portion of the checksum bit vector. In another embodiment, the generation of the checksum bit vector is performed recursively. Alternatively, only a first component vector of the checksum bit vector is generated. The error indicator provides an indication as to whether the received codeword contains errors in the information bits or not. In an embodiment, generating the error indicator includes determining a Hamming weight of the generated portion of the checksum bit vector and comparing the Hamming weight to a threshold. In an embodiment, the LDPC-encoded codeword is declared error-free if the Hamming weight is lower than the threshold.

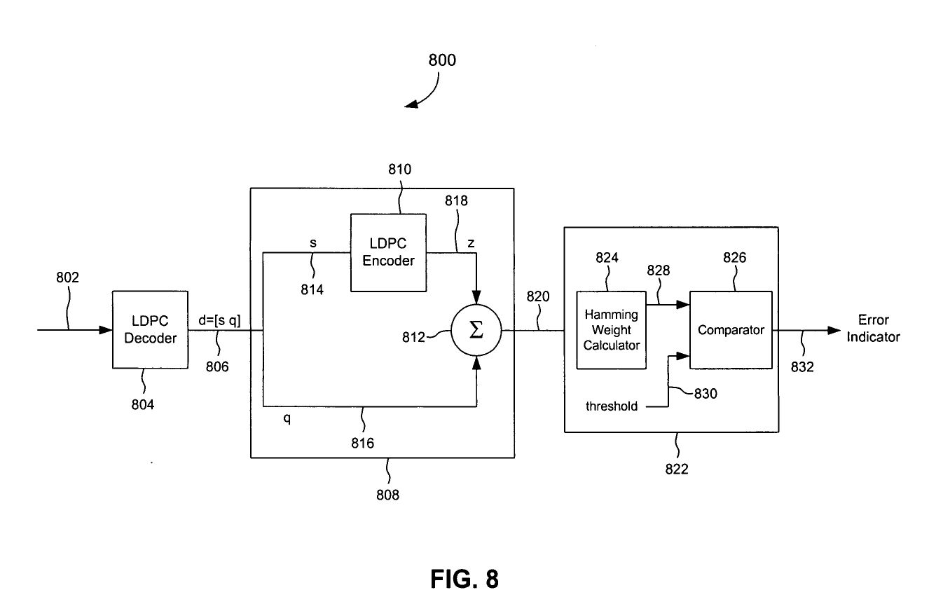

FIG. 8 is a high-level illustration of an apparatus 800 that may be used to implement the above described methods. Apparatus 800 includes an LDPC decoder 804, a checksum computing module 808, and an LDPC error indication module 822. In an embodiment, a received LDPC-encoded codeword 802 is acted on by LDPC decoder 804 to generate a decoded codeword 806. Decoded codeword 806 includes information bit vector s 814 and parity check bit vector q 816.

Checksum computing module 808 is configured to receive decoded codeword 806 and generate at least a portion of a checksum vector y 820. In an embodiment, checksum computing module 808 includes an LDPC encoder 810 and a summing module 812. LDPC encoder 810 is configured to receive and re-encode decoded information bit vector s 814 to generate re-encoded parity check bit vector z 818. Summing module 812 is configured to sum re-encoded parity check bit vector z 818 and decoded parity check bit vector q 816 to generate vector y 820.

LDPC error indication module 822 is configured to generate an error indicator 832 for the received LDPC encoded codeword 802 based on checksum vector y 820. In an embodiment, LDPC error indication module 822 includes a Hamming weight determination module 824, which receives checksum vector y 820 and outputs a Hamming weight value 828. Hamming weight value 828 is then input into a comparator module 826, which also receives a threshold value 830, compares Hamming weight value 828 and threshold value 830, and outputs an error indicator value 832 based on the comparison.

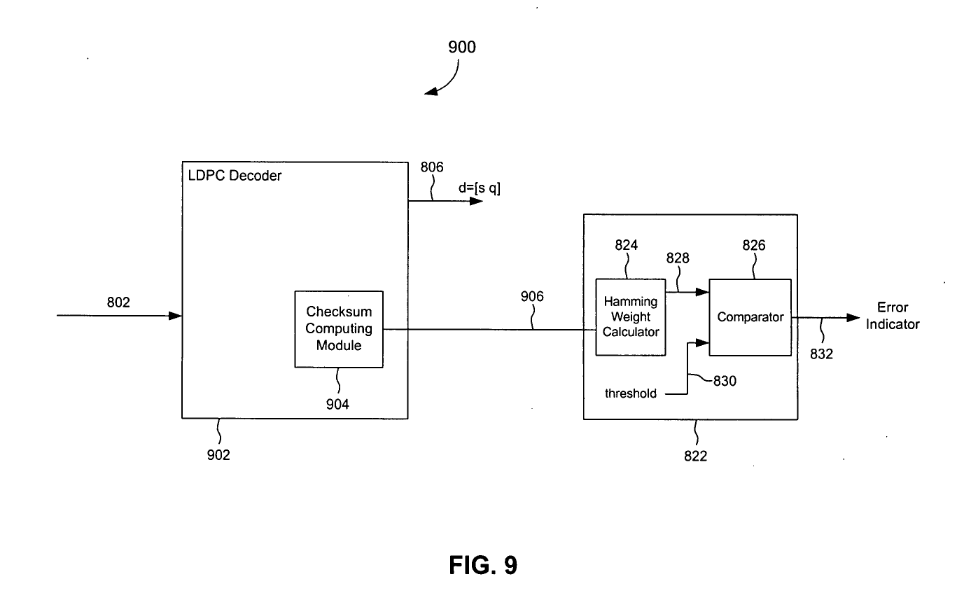

FIG. 9 illustrates another apparatus 900, which may also be used to implement the above described methods. Similar to apparatus 800, apparatus 900 includes an LDPC error indication module 822. In an embodiment, apparatus 900 uses a modified LDPC decoder 902 that includes a checksum computing module 904 to replace LDPC decoder 804 and checksum computing module 808 of apparatus 800. Alternatively, apparatus 900 uses LDPC decoder 804 as in apparatus 800 and a checksum computing module similar to module 904 but located externally to the decoder.

Accordingly, in either embodiment, apparatus 900 does not require a LDPC encoder 810 or a summing module 812. Instead, checksum computing module 904 acts on information readily available in LDPC decoder 902 (or decoder 804 in the alternative embodiment) to generate a checksum vector y 906. LDPC error indication module 822, as in apparatus 800, acts on vector y 906 to generate error indicator 832.

In an embodiment, checksum computing module 904 is a recursive checksum computing module, which recursively generates vector y 906 or a portion thereof. In an embodiment, checksum computing module 904 generates only a first component vector of the checksum vector.

As noted above, checksum computing module 904 may be embedded in or located externally to the LDPC decoder. In an embodiment, checksum computing module 904 is implemented using a logic circuit. Alternatively, checksum computing module 904 is implemented in software.

A. Full LDPC Parity Check Re-Encoding Method

As described above in section I, a parity check bit vector may include a plurality of component parity vectors. For example, the rate ⅔ LDPC codeword associated with H as given in Equation (1) includes 8 parity bit vectors p₁, p₂, p₃, p₄, p₅, p₆, p₇, and p₈.

The full LDPC parity check re-encoding method works by fully re-encoding the parity check bit vector z (as illustrated in FIG. 5) as to generate all its component parity vectors. The method then proceeds to compare each of the re-encoded component parity vectors with a respective decoded component parity check vector (component of vector q, as illustrated in FIG. 5). Alternatively, the method compares vectors z and q instead of individually comparing their component vectors.

In an embodiment, error indication is made based on the Hamming distance between vectors z and q. This includes determining a count of the number of bits that differ between vectors z and q and using a pre-defined threshold to make error indication decisions. For example, if the calculated Hamming distance between vectors z and q is less than the pre-defined threshold, the frame is declared to be correctly decoded. Otherwise, the decoded frame is decided to have been in error.

In an embodiment, the Hamming distance between vectors z and q is calculated by finding the Hamming weight (number of ones) of a checksum vector y=[y₁ y₂ . . . yₙ], where yᵢ=zᵢ+qᵢ for i=1, . . . , n and the addition is performed over a Galois Field of 2 elements (GF(2)).

As would be appreciated by a person skilled in the art based on the teachings herein, other variations for making error indication decisions may also exist based on this full LDPC parity check re-encoding approach.

In implementation, full LDPC parity check re-encoding requires an additional encoder at the receiver. However, only about 4% of the number of gates used by the LDPC decoder are needed for the re-encoding due to the assumed dual-diagonal structure of the LDPC code parity check matrix.

B. Partial LDPC Parity Check Re-Encoding Method

As with the above described full LDPC parity check re-encoding method, partial LDPC parity check re-encoding also operates on hard decisions made after LDPC decoding. The decoder output, d, can be written as:

d=[sq₁q₂q₃q₄q₅q₆q₇q₈] (2)

where s corresponds to the decoded systematic bits and qᵢ represents the P^{th} group of decoded parity bits.

The method then relies on the P×8 P matrix B=[I I I I I I I I], which is a horizontal concatenation of eight P×P identity matrices. From equation (1), it follows that:

BHc^{T}=0. (3)

where c=[m p₁ p₂ p₃ p₄ p₅ p₆ p₇ p₈].

Note, however that BH=[Y₁ Y₂ . . . Y₁₅ Y₁₆ I 0 0 0 0 0 0 0], where Yᵢ=X_{1,i}+X_{2,i}+ . . . +X_{8,i}. Thus, expanding equation (3):

[Y₁ Y₂ . . . Y₁₅ Y₁₆ I 0 0 0 0 0 0 0][m p₁ p₂ p₃ p₄ p₅ p₆ p₇ p₈]T=0, which implies:

[Y₁Y₂ . . . Y₁₅Y₁₆]m^{T}+p₁=0, (4)

or

[Y₁Y₂ . . . Y₁₅Y₁₆]m_{T}=p₁, (5)

since operations are performed over GF(2).

Similarly, BHd^{T}=[Y₁ Y₂ . . . Y₁₅ Y₁₆] s^{T}+q₁, and from equation (5), z₁=[Y₁ Y₂ . . . Y₁₅ Y₁₆]s^{T}, where z₁ is the first vector of re-encoded parities using the vector s as a message vector. Accordingly, it follows that:

BHd^{T}=z₁+q₁, (6)

or y₁=z₁+q₁=BHd^{T}. (7)

Note that y₁ represents the first component vector of the checksum vector y, which according to equation (7) can be calculated as the XOR of the re-encoded parities z₁, and the decoded parities q₁. However, also according to equation (7), actual re-encoding (using an encoder as in the full re-encoding method) to calculate the parities z₁, can be avoided, as y₁ can be readily determined from BHd^{T}, which can be determined at the decoder as a by-product of LDPC decoding.

In an embodiment, partial LDPC parity check re-encoding operates by checking whether y₁=0 to make error indication decisions. In other words, partial LDPC parity check re-encoding only determines whether the first component vector of re-encoded parities z₁, agrees with the first component vector of decoded parities q₁, for error determination. As will be further described below, this approach is inferior in terms of performance to the full re-encoding method, but requires minimal implementation cost, consuming only about 0.1% of the number of logic gates used by an LDPC decoder.

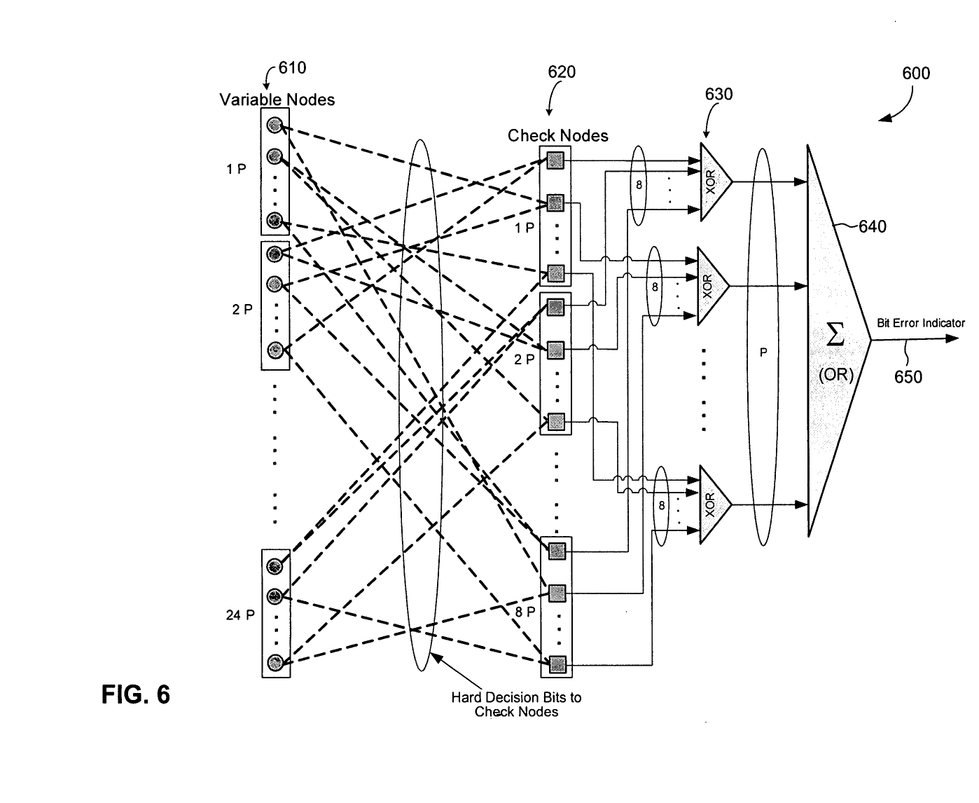

FIG. 6 illustrates an exemplary circuit implementation 600 of the partial LDPC parity check re-encoding method. Variable nodes 610 and check nodes 620 implement the computation of the matrix product Hd^{T} Accordingly, the Hamming weight of the checksum vector y₁=BHd^{T} can be determined using a first logic layer 630 of XOR gates, the outputs of which are summed using an OR gate 640 to generate a bit error indicator 650. If the output of OR gate 640 is zero, no error is indicated. Otherwise, an error indication is generated.

C. Alternative Full LDPC Parity Check Re-Encoding Method

An alternative full LDPC parity check method recursively generates the component vectors of the checksum vector y=[y₁ y₂ . . . yₙ]. For ease of illustration, the method is illustrated below with respect to a rate ⅔ LDPC code having 8 parity component vectors.

Assuming that d=[s q₁ q₂ q₃ q₄ q₅ q₆ q₇ q₈] is the decoded codeword at the decoder output and z=[z₁ z₂ z₃ z₄ z₅ z₆ z₇ z₈] is the vector of re-encoded parity bits, the first component vector y₁ of the checksum vector y can be efficiently computed using y₁=BHd^{T}, as shown above in equation (7). This eliminates the need to perform a full re-encoding of vector s.

Note that

Hd^{T}=[w₁w₂w₃w₄w₅w₆w₇w₈]^{T} (8)

where each wᵢ represents the bits (i−1)P+1 through iP of the final parities Hd^{T}. Also, note that

w₁^{T}=[X_{1,1}X_{1,2} . . . X_{1,16}]s^{T}+X(q₁)^{T}+(q₂)^{T} (9)

where equation (9) is the first row of the result obtained from a brute force multiplication of matrix H shown in equation (1) and d^{T}=[s q₁ q₂ q₃ q₄ q₅ q₆ q₇ q₈]^{T}.

Also, by definition, since z=[z₁ z₂ z₃ z₄ z₅ z₆ z₇ z₈] is the vector of re-encoded parity bits that result from re-encoding the vector s, then it follows that:

0=[X_{1,1}X_{1,2} . . . X_{1,16}]s^{T}+X(z₁)^{T}+(z₂)^{T}. (10)

Adding equations (9) and (10) over GF(2) and noting that yᵢ=zᵢ+qᵢ, it follows that:

(w₁)^{T}=X(y₁)^{T}+(y₂)^{T}, (11)

which can be re-arranged in a more convenient form as:

y₂=w₁+X^{T}y₁. (12)

The remaining component vectors of y=[y₁ y₂ . . . yₙ] are then calculated recursively extending the approach above. Then, once the Hamming weight of each of the component vectors yᵢ is calculated, the Hamming weight of vector y can be determined and compared against the pre-determined threshold to make error indication decisions. Alternative methods for making error indication decisions can also be obtained by using the weight of the vector [y₁ . . . yⱼ] for j=1, . . . , n to compare to the pre-determined threshold. For example, for j=1, only the weight of y₁ is used, and with a threshold of zero, the partial re-encoding method of section II.A is obtained. On the other hand, j=8 and a finite threshold yield the full re-encoding method of section I.A.

In implementation, w₁, can be obtained from the output of the first block of P parities (check nodes block) in the circuitry of FIG. 6. An XOR of w₁, with a shifted version of y₁ results in the vector y₂. Similarly, y₃ can be computed using w₂ and y₂, and so on to calculate the checksum vector y.

D. Simulation Results

Tables 4 and 5 below compare the performance of the full LDPC parity check re-encoding method (section II.A) and the partial LDPC parity check re-encoding method (section II.B), with respect to two exemplary length 2016 and length 1728 LDPC codewords. An error indication threshold of value 6 is used for the full LDPC parity check re-encoding method in the performance results below. This value was shown in simulation to provide the best P_{FA} and P_{M} tradeoff. As would be understood by a person skilled in the art, the larger is the threshold, the higher is P_{M} and the lower is P_{FA}, and inversely.

Tables 4 and 5 indicate that the full LDPC parity check re-encoding method significantly outperforms the partial LDPC parity check re-encoding method in all respects, for both exemplary LDPC codes. Yet, both methods may have unacceptable P_{FA} and P_{M} for certain frame error rates.

TABLE 4
Performance with Length 2016 LDPC Codeword

| | |
|---|---|
| Full Re-Encoding | Partial Re-encoding |

| FER | P_{FA} | P_{M} | P_{FA} | P_{M} |
|---|---|---|---|---|
| 0.677 | 0.00084 | <2.0 × 10⁻⁸ | 0.0057 | 1.8 × 10⁻⁷ |
| 0.307 | 0.00044 | 6.4 × 10⁻⁸ | 0.0042 | 2.7 × 10⁻⁷ |
| 0.076 | 9.3 × 10⁻⁵ | <2.0 × 10⁻⁸ | 0.0012 | 7.8 × 10⁻⁸ |

TABLE 5
Performance with Length 1728 LDPC Codeword

| | |
|---|---|
| Full Re-Encoding | Partial Re-encoding |

| FER | P_{FA} | P_{M} | P_{FA} | P_{M} |
|---|---|---|---|---|
| 0.90 | 0.00053 | 1.3 × 10⁻⁷ | 0.0033 | 6.4 × 10⁻⁷ |
| 0.29 | 0.00035 | 4.4 × 10⁻⁷ | 0.0041 | 5.9 × 10⁻⁷ |
| 0.077 | 8.1 × 10⁻⁵ | 4.9 × 10⁻⁸ | 0.0013 | 9.7 × 10⁻⁸ |

E. Hybrid CRC Checking and LDPC Parity Check Re-Encoding Method

As noted in the previous section, both the full LDPC parity check re-encoding and the partial LDPC parity check re-encoding methods, when used alone, may result in unacceptable P_{FA} or P_{M} under certain frame error rate conditions. In this section, a hybrid CRC checking and LDPC parity check re-encoding method is described, which may be used to enhance the performance of re-encoding methods.

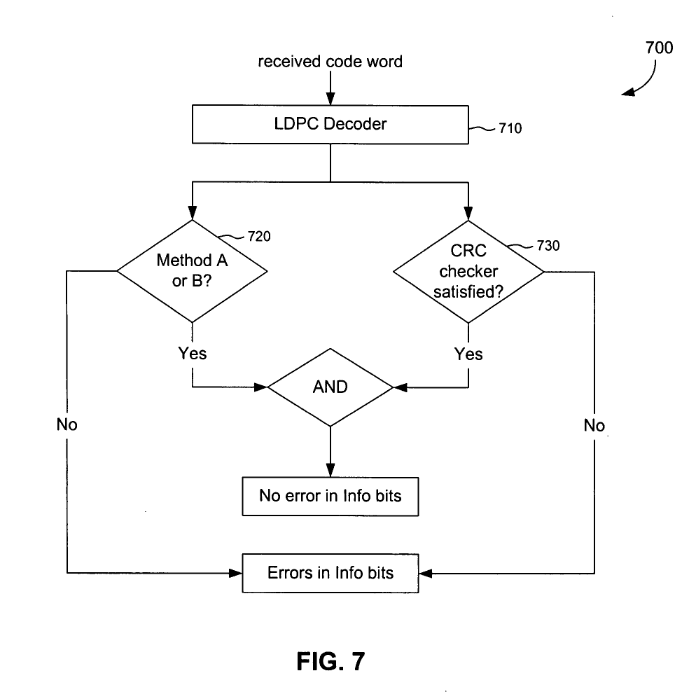

FIG. 7 is a process flowchart 700 that illustrates a hybrid method for error indication using LDPC parity check re-encoding and CRC checking. Process flowchart 700 begins in step 710, which includes receiving a codeword and performing LDPC decoding on the received codeword. Subsequently, the output of the LDPC decoder is simultaneously acted on by a LDPC parity check re-encoding method, in step 720, and a CRC checking method, in step 730. Note that “Method A or B” in step 720 refers to either the full LDPC parity check re-encoding or the partial LDPC parity check re-encoding methods. Also note that implementation of the full LDPC parity check re-encoding method can be achieved either using an actual encoder or using the alternative recursive method.

If both the LDPC parity check re-encoding method, step 720, and the CRC checking method, step 730, result in no error determination, then the information bits are declared error-free. Otherwise, if either results in an error determination, then the information bits are declared to contain errors, and an error indication is generated. For example, using the full LDPC parity check re-encoding method in step 720, the codeword is declared error-free if and only if both the Hamming distance between vectors z (re-encoded parities) and q (decoded parities) is less than a given threshold and the CRC check is satisfied. Similarly, using the partial LDPC parity check re-encoding method in step 720, the codeword is declared error-free if and only if the first component vector y₁ of the checksum vector is equal to zero and the CRC check is satisfied.

Tables 6 and 7 below illustrate the performance of the above described hybrid approach (with both the full re-encoding and the partial re-encoding methods) for two exemplary sets of CRC and LDPC code lengths. Note that the miss probability P_{M} is reduced to less than one in 50 million codewords across all FER scenarios. Further, note that the addition of CRC checking does not affect the probability of false alarms P_{FA} compared with solely using full re-encoding or partial re-encoding.

TABLE 6
Performance with CRC of Length 16 with
Length 2016 LDPC Codeword

| | |
|---|---|
| Full Re-Encoding | Partial Re-Encoding |

| FER | P_{FA} | P_{M} | P_{FA} | P_{M} |
|---|---|---|---|---|
| 0.677 | 0.00084 | <2.0 × 10⁻⁸ | 0.0057 | <2.0 × 10⁻⁸ |
| 0.307 | 0.00044 | <2.0 × 10⁻⁸ | 0.0042 | <2.0 × 10⁻⁸ |
| 0.076 | 9.3 × 10⁻⁵ | <2.0 × 10⁻⁸ | 0.0012 | <2.0 × 10⁻⁸ |

TABLE 7
Performance with CRC of Length 24 with
Length 1728 LDPC Codeword

| | |
|---|---|
| Full Re-Encoding | Partial Re-Encoding |

| FER | P_{FA} | P_{M} | P_{FA} | P_{M} |
|---|---|---|---|---|
| 0.90 | 0.00053 | <2.0 × 10⁻⁸ | 0.0033 | <2.0 × 10⁻⁸ |
| 0.29 | 0.00035 | <2.0 × 10⁻⁸ | 0.0041 | <2.0 × 10⁻⁸ |
| 0.077 | 8.1 × 10⁻⁵ | <2.0 × 10⁻⁸ | 0.0013 | <2.0 × 10⁻⁸ |

Accordingly, an error indication approach based on the use of a short CRC coupled with fully or partially re-encoding the output of the LDPC decoder achieves the performance required in applications requiring very low false alarm and miss probabilities. These results directly apply to LDPC codes with dual-diagonal structured parity check matrix, though it is expected that other LDPC codes will allow similar techniques.

### III. Conclusion

While various embodiments of the present invention have been described above, it should be understood that they have been presented by way of example only, and not limitation. It will be understood by those skilled in the relevant art(s) that various changes in form and details may be made therein without departing from the spirit and scope of the invention as defined in the appended claims. Accordingly, the breadth and scope of the present invention should not be limited by any of the above-described exemplary embodiments, but should be defined only in accordance with the following claims and their equivalents.

What is claimed is:

1. A method of providing error indication for low density parity check (LDPC) encoded information, comprising:
(a) receiving an LDPC-encoded codeword;
(b) decoding the LDPC-encoded codeword to generate decoded information bits and parity check bits;
(c) generating at least a portion of a checksum bit vector based on one or more of the decoded information bits, the parity check bits, and information derivative from step (b); and
(d) generating a first error indicator for the received LDPC-encoded codeword based on the generated portion of the checksum bit vector.

2. The method of claim 1, wherein step (c) comprises:
(e) LDPC re-encoding the decoded information bits to generate re-encoded parity check bits; and
(f) summing the generated re-encoded parity check bits and respective ones of the decoded parity check bits to generate said portion of the checksum bit vector.

3. The method of claim 2, wherein step (d) comprises:
(g) determining a Hamming weight of said portion of the checksum bit vector; and
(h) comparing said Hamming weight to a threshold to generate said first error indicator.

4. The method of claim 3, wherein the LDPC-encoded codeword is declared error-free if said Hamming weight is less than said threshold.

5. The method of claim 1, wherein step (c) comprises:
(e) recursively determining said portion of the checksum bit vector.

6. The method of claim 5, wherein step (d) comprises:
(f) determining a Hamming weight of said portion of the checksum bit vector; and
(g) comparing said Hamming weight to a threshold to generate said first error indicator.

7. The method of claim 6, wherein the LDPC-encoded codeword is declared error-free if said Hamming weight is less than said threshold.

8. The method of claim 1, wherein step (c) comprises:
(e) determining a first component vector of said checksum bit vector.

9. The method of claim 8, wherein step (d) comprises:
(f) determining a Hamming weight of said first component vector of said checksum vector; and
(g) comparing said Hamming weight to a threshold to generate said first error indicator.

10. The method of claim 9, wherein said LDPC-encoded codeword is declared error-free if said Hamming weight is equal to said threshold.

11. The method of claim 10, wherein said threshold is equal to zero.

12. The method of claim 1, further comprising:
(e) performing Cyclic Redundancy Code (CRC) checking on the decoded information bits to generate a second error indicator; and
(f) generating an error indication for the received LDPC-encoded codeword based on the first and second error indicators.

13. The method of claim 12, wherein the LDPC-encoded codeword is declared error-free if and only if both the first and second error indicators indicate that the LDPC-encoded codeword is error-free.

14. An apparatus for generating error indication for low density parity check (LDPC) encoded information, comprising:
(a) an LDPC decoder configured to receive an LDPC encoded codeword and generate a decoded codeword;
(b) a checksum computing module configured to receive said decoded codeword or information derived from said decoder and generate at least a portion of a checksum vector; and
(c) an LDPC error indication module configured to generate a first error indicator for said LDPC encoded codeword based on said checksum vector.

15. The apparatus of claim 14, wherein said checksum vector computing module comprises:
(d) an LDPC encoder configured to re-encode information bits of the decoded codeword to generate re-encoded parity check bits; and
(e) a summing module configured to sum said re-encoded parity check bits and parity check bits of the decoded codeword.

16. The apparatus of claim 14, wherein said error indication module, comprises:
(d) a Hamming weight determination module configured to determine a Hamming weight of said portion of said checksum vector; and
(e) a comparator module configured to compare said determined Hamming weight to a threshold and output said first error indicator.

17. The apparatus of claim 16, wherein said Hamming weight determination module comprises a logic circuit.

18. The apparatus of claim 17, wherein said logic circuit comprises a plurality of XOR logic gates and a summing OR logic gate.

19. The apparatus of claim 14, wherein said checksum computing module comprises a recursive checksum vector computing module.

20. The apparatus of claim 14, further comprising:
(d) a Cyclic Redundancy Code (CRC) checking module configured to generate a second error indicator based on the decoded codeword; and
(e) an error indication module configured to generate an error indication for said LDPC encoded codeword based on the first and second error indicators.

21. The apparatus of claim 14, wherein said checksum computing module is integrated in said LDPC decoder.

22. The apparatus of claim 14, wherein said checksum computing module is implemented using hardware and/or software.

23. The method of claim 5, wherein step (e) comprises:
(f) generating a first component vector of said checksum bit vector using said information derived from step (b); and
(g) generating each subsequent component vector of said checksum bit vector based on one or more of immediately preceding generated component vector and said information derived from step (b).

24. The apparatus of claim 21, wherein said checksum computing module is configured to recursively generate said portion of the checksum vector.
